(19) United States
(12) Patent Application Publication
(10) Pub. No.: US 2024/0369940 A1
(43) Pub. Date: Nov. 7, 2024

(54) PATTERN SELECTION FOR SOURCE MASK OPTIMIZATION AND TARGET OPTIMIZATION

(71) Applicant: ASML NETHERLANDS B.V., Veldhoven (NL)

(72) Inventors: Duan-Fu Stephen HSU, Fremont, CA (US); Ningning JIA, Shenzhen (CN); Xiaohui JIANG, Shenzhen (CN); Gengxin LIU, Shenzhen (CN)

(73) Assignee: ASML NETHERLANDS B.V., Veldhoven (NL)

(21) Appl. No.: 18/572,764

(22) PCT Filed: Jun. 17, 2022
(86) PCT No.: PCT/EP2022/066586

§ 371 Date: Dec. 20, 2023

(30) Foreign Application Priority Data
Jul. 13, 2021 (WO) PCT/CN2021/105988

(51) Int. Cl. G03F 7/00; G03F 1/36

(52) U.S. Cl. CPC G03F 7/70441; G03F 1/36; G03F 7/705

(57) ABSTRACT

Apparatuses, systems, and methods for selecting a subset of critical patterns from a plurality of patterns of a design layout. In some embodiments, the method includes accessing diffraction order data based on the plurality of patterns that represent features to be formed on at least a portion of a substrate, the diffraction order data including a plurality of peaks corresponding to the plurality of patterns. The method also includes identifying a subset of representative peaks from the plurality of peaks according to one or more grouping criteria, the identifying including identifying a first representative peak that covers another peak colinear with the first representative peak, wherein the first representative peak is a discrete peak having a frequency that is an integer multiple of frequency of another discrete peak. The method further includes selecting the subset of critical patterns corresponding to the subset of representative peaks.

### CROSS-REFERENCE TO RELATED APPLICATIONS

This application claims priority of International application PCT/CN2021/105988 which was filed on Jul. 13, 2021 and which is incorporated herein in its entirety by reference.

### TECHNICAL FIELD

The embodiments provided herein relate to pattern selection for lithography, and more specifically, to pattern selection for source mask optimization and target optimization.

### BACKGROUND

In manufacturing processes of integrated circuits (ICs), a mask can be used in lithography may contain a circuit pattern corresponding to an individual layer of the IC, and this circuit pattern can be imaged onto a target portion (e.g., comprising one or more dies) on a substrate (e.g., a silicon wafer) that has been coated with a layer of radiation-sensitive material (e.g., resist). The substrate may undergo various procedures, such as priming, resist coating, and a soft bake. After exposure, the substrate may be subjected to other procedures, such as a post-exposure bake (PEB), development, a hard bake and measurement/inspection of the imaged features. This array of procedures is used as a basis to pattern an individual layer of a device, e.g., an IC. Such a patterned layer may then undergo various processes such as etching, ion-implantation (doping), metallization, oxidation, chemo-mechanical polishing, etc., to finish off an individual layer. If several layers are required, then the procedures, or a variant thereof, will be repeated for each new layer. Eventually, an array of devices will be present on the substrate (wafer). These devices are then separated from one another by a technique such as dicing or sawing, and then the individual devices can be mounted on a carrier, connected to pins, etc.

As semiconductor manufacturing processes continue to advance, critical layers of leading-edge devices can be manufactured using optical lithographic projection systems known as scanners that project a mask image onto a substrate using illumination from a deep-ultraviolet laser light source, creating individual circuit features having dimensions well below 100 nm, i.e., less than half the wavelength of the projection light. This process in which features with dimensions smaller than the classical resolution limit of an optical projection system are printed, is commonly known as low-kI lithography.

For low-kl lithography, optimization of both source and mask (e.g., source and mask optimization or SMO) is needed to ensure a viable process window for printing critical patterns. Existing algorithms (e.g. Socha et. al. Proc. SPIE vol. 5853, 2005, p. 180) generally discretize illumination into independent source points and mask into diffraction orders in the spatial frequency domain, and separately formulate a cost function based on process window metrics such as exposure latitude which can be predicted by optical imaging models from source point intensities and mask diffraction orders. Then standard optimization techniques are used to minimize the objective function.

Conventional SMO techniques are computationally expensive, especially for complicated designs. Accordingly, it is generally only practical to perform source optimization for simple repeating designs such as memory designs (e.g., Flash, DRAM and SRAM). Meanwhile, the full chip includes other more complicated designs such as logic and gates. As the SMO source optimization is only based on limited small areas of certain designs, it is difficult to guarantee that the source will work well for the designs that are not included in the SMO process. Further, as the physical sizes of IC components continue to shrink, accuracy and efficiency in pattern selection and SMO on the selected critical patterns become more important.

### SUMMARY

Embodiments of the present disclosure provide apparatuses, systems, and methods for pattern selection.

In some embodiments, a method of selecting a subset of critical patterns from a plurality of patterns of a design layout is provided. The method comprises accessing diffraction order data based on the plurality of patterns that represent features to be formed on at least a portion of a wafer, the diffraction order data including a plurality of peaks corresponding to the plurality of patterns; identifying a subset of representative peaks from the plurality of peaks according to one or more grouping criteria, comprising identifying a first representative peak of the subset of representative peaks that covers another peak colinear with the first representative peak, wherein the first representative peak is a discrete peak having a frequency that is an integer multiple of frequency of another discrete peak; and selecting the subset of critical patterns corresponding to the subset of representative peaks.

In some embodiments, a system for selecting a subset of critical patterns from a plurality of patterns of a design layout is provided. The system comprises a memory storing a set of instructions; and at least one processor configured to execute the set of instructions to cause the system to perform: accessing diffraction order data based on the plurality of patterns that represent features to be formed on at least a portion of a wafer, the diffraction order data including a plurality of peaks corresponding to the plurality of patterns; identifying a subset of representative peaks from the plurality of peaks according to one or more grouping criteria, comprising identifying a first representative peak of the subset of representative peaks that covers another peak colinear with the first representative peak, wherein the first representative peak is a discrete peak having a frequency that is an integer multiple of frequency of another discrete peak; and selecting the subset of critical patterns corresponding to the subset of representative peaks.

In some embodiments, a non-transitory computer readable medium that stores a set of instructions that is executable by at least one processor of a system to cause the system to perform a method of selecting a subset of critical patterns from a plurality of patterns of a design layout. The method comprises accessing diffraction order data based on the plurality of patterns that represent features to be formed on at least a portion of a wafer, the diffraction order data including a plurality of peaks corresponding to the plurality of patterns; identifying a subset of representative peaks from the plurality of peaks according to one or more grouping criteria, comprising identifying a first representative peak of the subset of representative peaks that covers another peak colinear with the first representative peak, wherein the first representative peak is a discrete peak having a frequency that is an integer multiple of frequency of another discrete peak; and selecting the subset of critical patterns corresponding to the subset of representative peaks.

In some embodiments, a method of performing a design target optimization. The method comprises performing a first source mask optimization (SMO) to a subset of critical patterns of a plurality of patterns of a design layout; optimizing layout retarget rules based on one or more feature limiters; generating a set of clips based on the optimized layout retarget rules; and performing a second SMO to the subset of critical patterns and the generated set of clips to obtain optimized source.

In some embodiments, a system for performing a design target optimization. The system comprises a memory storing a set of instructions; and at least one processor configured to execute the set of instructions to cause the system to perform: performing a first source mask optimization (SMO) to a subset of critical patterns of a plurality of patterns of a design layout; optimizing layout retarget rules based on one or more feature limiters; generating a set of clips based on the optimized layout retarget rules; and performing a second SMO to the subset of critical patterns and the generated set of clips to obtain optimized source.

In some embodiments, a non-transitory computer readable medium that stores a set of instructions that is executable by at least one processor of a system to cause the system to perform a method of performing a design target optimization. The method comprises performing a first source mask optimization (SMO) to a subset of critical patterns of a plurality of patterns of a design layout; optimizing layout retarget rules based on one or more feature limiters; generating a set of clips based on the optimized layout retarget rules; and performing a second SMO to the subset of critical patterns and the generated set of clips to obtain optimized source.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a diagram of an example lithographic projection apparatus, consistent with embodiments of the present disclosure.

FIG. 2 is a block diagram of an example system for performing source mask optimization (SMO) pattern selection, consistent with embodiments of the present disclosure.

FIG. 3 illustrates a plurality of subcomponents included in diffraction order (DO) map processing component, consistent with embodiments of the present disclosure.

FIG. 4A illustrates example peaks corresponding to non-periodic patterns in DO maps processed by one or more components of the system in FIG. 2, consistent with embodiments of the present disclosure.

FIG. 4B illustrates extraction of peak centers and contours of example peaks corresponding to periodic patterns and non-periodic patterns, consistent with embodiments of the present disclosure.

FIG. 5 illustrates example grouping criteria used for grouping the peaks in DO maps, consistent with embodiments of the present disclosure.

FIG. 6 is a process flowchart representing an example process of pattern selection, in accordance with some embodiments of the present disclosure.

FIG. 7 is a process flowchart representing an example process of SMO design target optimization, in accordance with some embodiments of the present disclosure.

FIG. 8 is a process flowchart representing an example method for selecting a subset of critical patterns from a plurality of patterns of a design layout, in accordance with some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

As the sizes of features and transistors continues to decrease, the ability to faithfully recreate a design layout on a substrate is becoming increasingly difficult. Manufacturing equipment can introduce artifacts or defects when trying to deposit such small features onto the substrate. To account for the physical difficulty of recreating IC layouts at such microscopic scales, IC manufactures rely on techniques such as computational lithography to analyze and modify a design to account for known artifacts of the physical manufacturing process. By adjusting the layout, mask, or other lithography data prior to manufacture to account for known manufacturing artifacts, IC manufacturers can better recreate the originally intended design.

In order to identify what patterns or features may result in which physical artifacts, IC manufacturers can utilize enormous data sets to allow for accurate predictions. This can result in computationally expensive techniques that become increasingly complex as IC designs become increasingly complex.

Because of this increased computational complexity and the need for enormous pattern data sets, techniques that can reduce the complexity are important. Source mask optimization (SMO) is a type of Resolution Enhance Technique (RET) to provide solutions to optimize source and mask for critical design layers of technology nodes. In some embodiments, SMO is a process where mask design layout and illumination source are co-optimized for producing a high-fidelity image on the substrate. In general, SMO aims to achieve full chip pattern coverage while lowering the computation cost by intelligently selecting a small set of critical design patterns from the full set of clips to be used in SMO. SMO is performed only on these selected patterns to obtain an optimized source. The optimized source is then used to optimize the mask (e.g., using optical proximity correction (OPC) and lithography manufacturability check (LMC)) for the full chip, and the results are compared.

Pattern selection plays a key role in advanced tech-node process development. In some embodiments, a set of test patterns are generated to cover the full-chip design and the test patterns may include thru-pitch periodic patterns to cover the design rule and non-periodic patterns that may include weak points, hotspots, and critical patterns from the real design. The number of test patterns can be large and may still cause long runtime in SMO. To reduce runtime and speed up the development cycle, a pattern selection function was developed and is being used to select the representative patterns for optimization. The source can be optimized based on the selected patterns. Therefore, pattern selection is critical for SMO to ensure a robust pattern coverage, which can lead to superior source and mask optimization, and optical proximity correction (OPC) or other applications.

SMO pattern selection can be based on the classification and grouping of diffraction orders of patterns. Based on the diffraction orders grouping results, patterns with similar diffraction signatures can be grouped together, and a representative pattern for each group can be selected in SMO. In some embodiments, SMO pattern selection can be applied to periodic patterns, because their diffraction order peaks are discrete peaks, and it is easy to define peak centers and the grouping criteria (such as coverage criteria) between discrete peaks from those periodic patterns. Non-periodic patterns are critical as they may include a larger dimension than periodic patterns, so the impact on runtime is significant. However, for non-periodic patterns, SMO pattern selection may face challenges as the diffraction order signatures for non-periodic patterns may include continuous peaks, making it hard to define peak centers and coverage relationship. As a result, it is desirable to have improved pattern selection process for non-periodic patterns.

The embodiments of the present disclosure provide techniques for selecting a smaller representative set of target patterns from a larger set of target patterns, wherein the representative set of target patterns adequately represent the critical features of a design layout, e.g., a full chip design. The larger set of target patterns may comprise the entire design layout of a mask, or a substantially large portion of the design layout. Although the embodiments of the present disclosure is particularly suited to SMO, it is appreciated that the pattern selection algorithms can be applied to any situation where a bigger design layout can be represented adequately by intelligently selecting a smaller set of target patterns from the design layout.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

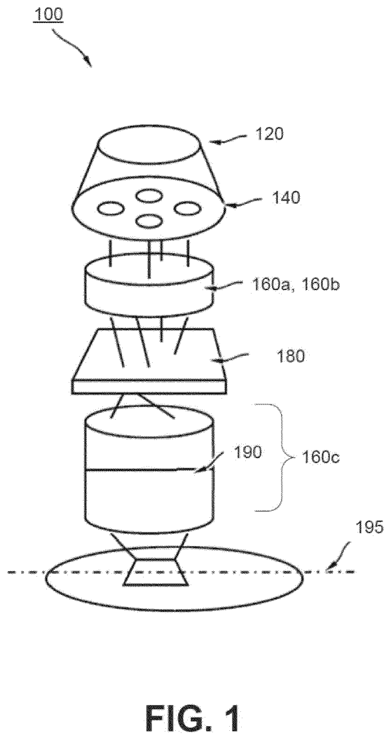

FIG. 1 illustrates an exemplary lithographic projection apparatus 100. Major components can include a radiation source 120, which can be a deep-ultraviolet excimer laser source or other type of source including an extreme ultra violet (EUV) source (as disclosed above, the lithographic projection apparatus itself need not have the radiation source), illumination optics which, e.g., define the partial coherence (denoted as sigma) and which may include optics 140, 160a and 160b that shape radiation from the source 120; a patterning device 180; and transmission optics 160c that project an image of the patterning device pattern onto a substrate plane 195. An adjustable filter or aperture 190 at the pupil plane of the projection optics can restrict the range of beam angles that impinge on the substrate plane 195, where the largest possible angle defines the numerical aperture of the projection optics NA=n sin(Θmax), wherein n is the refractive index of the media between the substrate and the last element of the projection optics, and Θmax is the largest angle of the beam exiting from the projection optics that can still impinge on the substrate plane 195.

In a lithographic projection apparatus, a source (e.g., radiation source 120) provides illumination (i.e., radiation) to a patterning device and projection optics direct and shape the illumination, via the patterning device, onto a substrate. The projection optics may include at least some of the components 140, 160a, 160b and 160c. An aerial image (AI) is the radiation intensity distribution at substrate level. A resist model can be used to calculate the resist image from the aerial image. The resist model is related only to properties of the resist layer (e.g., effects of chemical processes which occur during exposure, post-exposure bake (PEB) and development). Optical properties of the lithographic projection apparatus (e.g., properties of the illumination, the patterning device, and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each of which is hereby incorporated by reference in its entirety.

The patterning device (e.g., patterning device 180) can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as critical dimension (CD). A critical dimension of a device can be defined as the smallest width of a line or hole or the smallest space between two lines or two holes. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.
a programmable LCD array. An example of such a construction is given in U.S. Pat. No. 5,229,872, which is incorporated herein by reference.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

Variables of a patterning process are called “processing variables.” The patterning process may include processes upstream and downstream to the actual transfer of the pattern in a lithography apparatus. A first category can be variables of the lithography apparatus or any other apparatuses used in the lithography process. Examples of this category include variables of the illumination, projection system, substrate stage, etc. of a lithography apparatus. A second category may be variables of one or more procedures performed in the patterning process. Examples of this category include focus control or focus measurement, dose control or dose measurement, bandwidth, exposure duration, development temperature, chemical composition used in development, etc. A third category may be variables of the design layout and its implementation in, or using, a patterning device. Examples of this category can include shapes and/or locations of assist features, adjustments applied by a resolution enhancement technique (RET), CD of mask features, etc. A fourth category can be variables of the substrate. Examples include characteristics of structures under a resist layer, chemical composition and/or physical dimension of the resist layer, etc. A fifth category can be characteristics of temporal variation of one or more variables of the patterning process. Examples of this category include a characteristic of high frequency stage movement (e.g., frequency, amplitude, etc.), high frequency laser bandwidth change (e.g., frequency, amplitude, etc.) and/or high frequency laser wavelength change. These high frequency changes or movements are those above the response time of mechanisms to adjust the underlying variables (e.g., stage position, laser intensity). A sixth category can be characteristics of processes upstream of, or downstream to, pattern transfer in a lithographic apparatus, such as spin coating, post-exposure bake (PEB), development, etching, deposition, doping and/or packaging.

As will be appreciated that, many, if not all of these variables, can have an effect on a parameter of the patterning process and often a parameter of interest. Non-limiting examples of parameters of the patterning process may include critical dimension (CD), critical dimension uniformity (CDU), focus, overlay, edge position or placement, sidewall angle, pattern shift, etc. Often, these parameters express an error from a nominal value (e.g., a design value, an average value, etc.). The parameter values may be the values of a characteristic of individual patterns or a statistic (e.g., average, variance, etc.) of the characteristic of a group of patterns.

The values of some or all of the processing variables, or a parameter related thereto, may be determined by a suitable method. For example, the values may be determined from data obtained with various metrology tools (e.g., a substrate metrology tool). The values may be obtained from various sensors or systems of an apparatus in the patterning process (e.g., a sensor, such as a leveling sensor or alignment sensor, of a lithography apparatus, a control system (e.g., a substrate or patterning device table control system) of a lithography apparatus, a sensor in a track tool, etc.). The values may be from an operator of the patterning process.

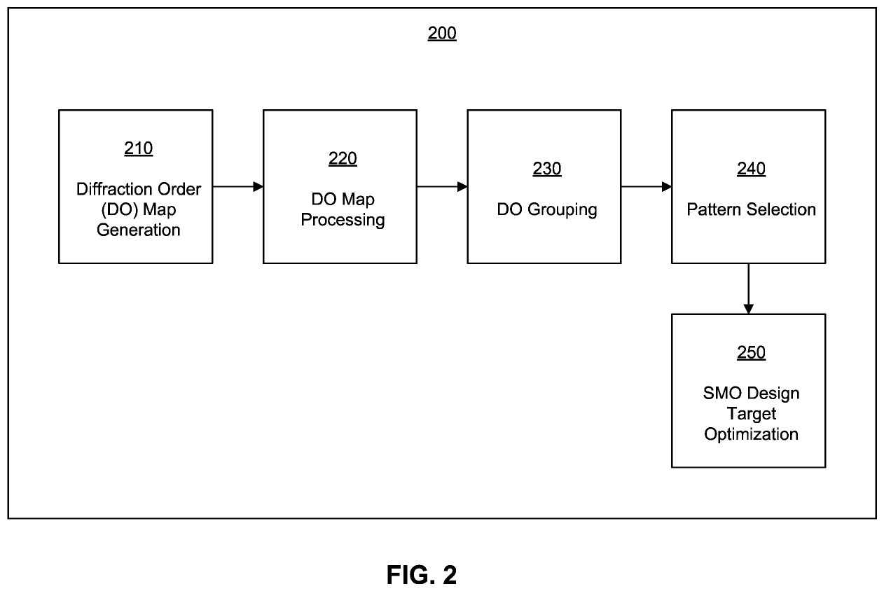

FIG. 2 is a block diagram of an exemplary system 200 for performing SMO pattern selection, consistent with embodiments of the present disclosure. In some embodiments, system 200 includes a diffraction order (DO) map generation component 210, a DO map processing component 220, a DO grouping component 230, a pattern selection component 240, and a SMO design target optimization component 250. In some embodiments, a design layout (e.g., comprising a layout in a standard digital format such as OASIS, GDSII, etc.) for which a lithographic process is to be optimized may include memory, test patterns and logic. From this design layout, the initial larger set of target patterns (clips) is identified. In some embodiments, a full set of clips is extracted, which represents all the complicated patterns in the design layout (e.g., about 50 to 1000 clips, or any suitable number of clips). It is to be understood that DO map is disclosed as a non-limiting example of various types or formats of DO data or DO information. The DO information/data can be in any suitable format or representation without departing from the scope of the present disclosure, such as a map or a table, etc.

In some embodiments, the initial larger set of clips may be provided a priori based on known critical feature areas in a design layout for image optimization. In some embodiments, the initial larger set of clips may be extracted from the entire design layout using automated (e.g., machine vision) or manual algorithm that identifies the critical feature areas. In some embodiments, the larger set of patterns may comprise different pattern types, such as gate or logic patterns, or may comprise patterns having various orientations. In some embodiments, the larger set of patterns may comprise 1-D patterns or 2-D patterns. In some embodiments, the larger set of patterns may comprise periodic patterns, non-periodic patterns, or iso-like patterns, including but not limited to line-space, line-end, contact features, angled features, or any type of features.

In some embodiments, the larger set of patterns may comprise patterns comprising a certain level of complexity, or patterns requiring particular attention or verification during the lithographic processing. For example, the patterns may comprise test structures complying to design rules, like 1D through pitch, staggered through pitch, commonly used design constructs or primitives (e.g., elbows, T shapes, H shapes), repeatedly used layout structures like memory cells (e.g., brick walls), memory periphery structures (e.g., hooks to memory cells), or patterns with known imaging issues from previous generation. In some embodiments, the larger set of patterns may comprise patterns having a predefined process window performance, or patterns comprising a sensitivity to process parameter variations.

In some embodiments, a small subset of patterns or clips (e.g., 15 to 50 clips, or any other suitable number) is selected from the initial larger set of clips. As explained below, the selection of the subset of patterns or clips is performed such that the process window of the selected patterns matches as closely as the process window for the larger set of critical patterns. The effectiveness of the selection can be measured by the total turn-around time or run time reduction in the combined pattern-selection and subsequent SMO process.

The present disclosure is not limited to any specific method, process, implementation or algorithm of generating a DO map. In some embodiments, DO map generation component 210 generates DO maps for the initial larger set of clips, where a respective DO map corresponds to a design pattern included in a clip of the initial larger set of clips. In some embodiments, the clips may be provided by the customer with test patterns. In some embodiments, the clips may be extracted from the design layout. In some embodiments, DO map generation component 210 generates the DO map from SMO based on Fourier Transform theory, e.g., 1-D or 2-D Fourier Transform, to render the images based on the target polygons in frequency domain. In some embodiments, due to the centrosymmetric characteristic |F(ωx,ωy)|=|F(−ωx,−ωy)| of Fourier Transform, the DO peaks are centrosymmetric. In some embodiments, the size of a DO image is 201 by 201 pixels, or other suitable sizes. In some embodiments, for array patterns, the DO map comprises discrete peaks in the frequency space. In some embodiments, for non-array patterns (e.g., 2D non-periodic patterns as disclosed herein), the DO maps comprise discrete or continuous peaks in the frequency domain.

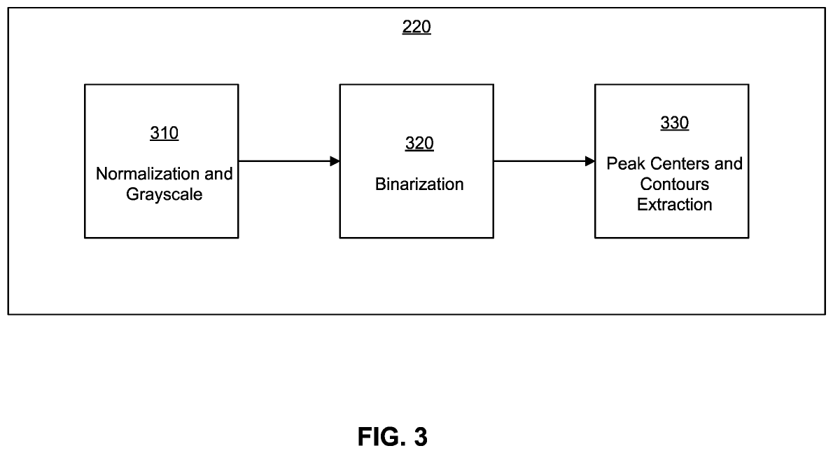

In some embodiments, DO map processing component 220 processes the generated DO maps via one or more image processing steps. FIG. 3 illustrates a plurality of subcomponents included in DO map processing component 220, including but not limited to, normalization and grayscale subcomponent 310, a binarization subcomponent 320, and a peak centers and contours extraction subcomponent 330, consistent with embodiments of the present disclosure.

In some embodiments, normalization and grayscale subcomponent 310 normalizes the DO maps. For example, normalization and grayscale subcomponent 310 normalizes the DO map based on a maximum intensity and a minimum intensity of the peak, and transforms the DO map into a grayscale map, e.g., based on a grayscale from 0 to 255. In some embodiments, the zeroth order of a respective DO map is removed.

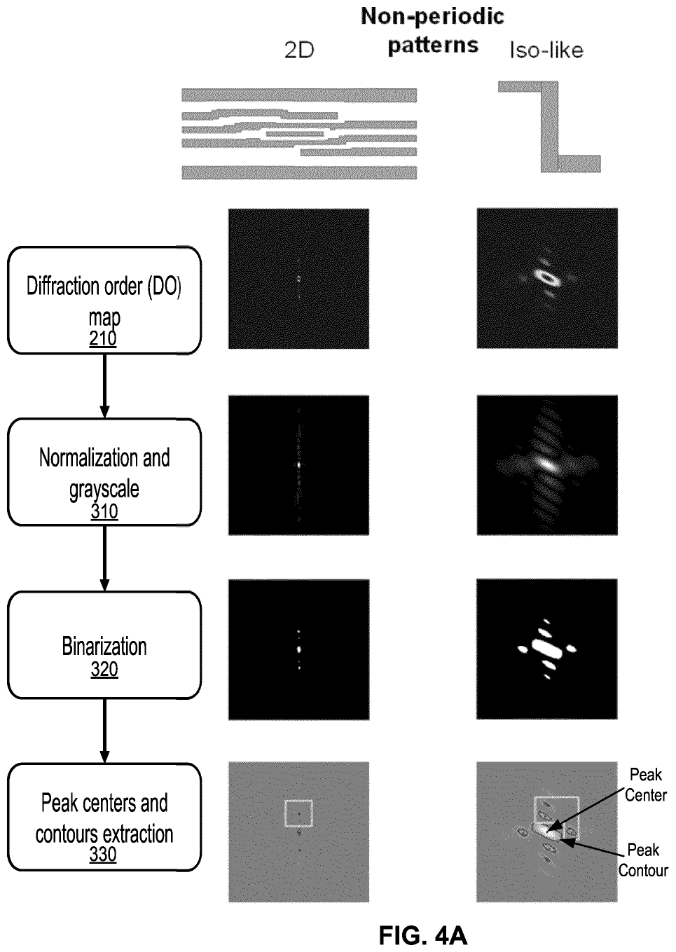

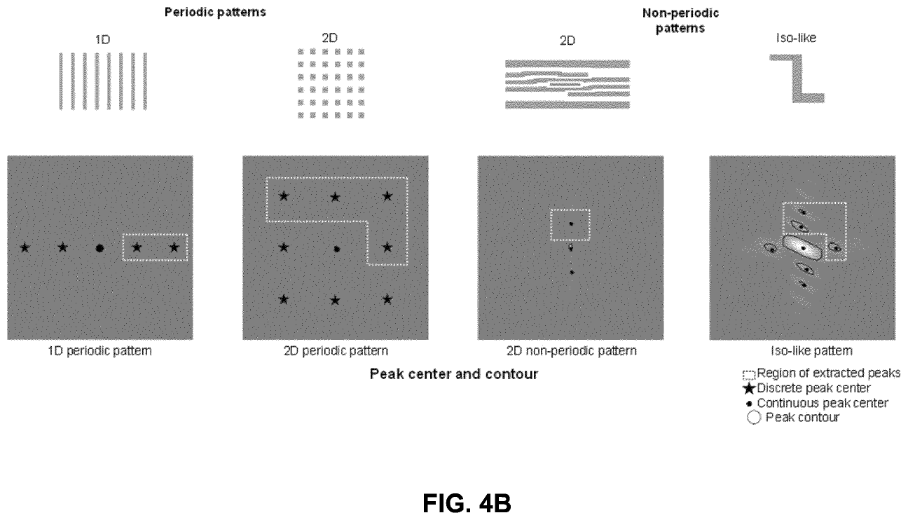

In some embodiments, binarization subcomponent 320 performs binarization to the gray-scaled map. Because the DO amplitudes or intensities of the peaks may vary in different clips, the normalization and binarization as disclosed herein can enhance the peak contour, such as the contour of the continuous peaks corresponding to the 2D non-periodic patterns (e.g., as shown in FIG. 4A), so as to extract the complete contour of the peaks in the corresponding DO maps. In some embodiments, a general minimum threshold (e.g., G_{minThresh}), e.g., a value of 20, 40, 60, or other suitable value, is applied on all images to filter out weak signals that may be noises (e.g., peaks with values below G_{minThresh}). Next, a clip specific minimum threshold (e.g., C_{minThresh}), corresponding to the intensity of the weakest peak of that clip, is applied to ensure that the weakest peak can be extracted. In some embodiments, the one or more thresholds correspond to the grayscale level (e.g., between 0 and 255) and can be tuned. In some embodiments, binarization subcomponent 320 can binarize the gray-scaled map using any suitable binary function, e.g., sigmoid, etc.

In some embodiments, extraction subcomponent 330 extracts the peak centers and peak contours from the DO map in the clip after binarization, as shown in the continuous peaks for the example 2-D non-periodic patterns (e.g., FIGS. 4A-4B). In some embodiments, the DO peaks of array patterns or periodic patterns are discrete peaks, whereas the DO peaks of the non-array patterns or non-periodic patterns include continuous peaks. In some embodiments, the distribution of contours in any direction is considered, without limiting to any particular direction(s) (e.g., not limited to x or y direction, the four directions, or the eight directions). As such, the raw peak contour can be considered at all directions. In some embodiments, the actual (e.g., precise) peak contour can be used in one or more processes as disclosed herein without approximation. Further, all DO peaks, including harmonic DO peaks, are extracted in the present disclosure. As a result, the accuracy in determining the peak coverage can be improved.

FIG. 4A illustrates example peaks corresponding to non-periodic patterns in DO maps processed by one or more components of system 200 of FIG. 2, or subcomponents of FIG. 3, consistent with embodiments of the present disclosure. FIG. 4B illustrates extraction of peak centers and contours of example peaks corresponding to periodic patterns and non-periodic patterns, consistent with embodiments of the present disclosure. In some embodiments, as shown in FIG. 4B, extraction subcomponent 330 performs image processing to have adjacent pixels with similar intensity to be included within a peak contour. In some embodiments, the pixels in the binarized image have intensity values of either 0 or 1, and extraction subcomponent 330 processes the binarized image to include pixels with intensity value of 1 in a peak contour. The peak center can be extracted from the bounding area of peak contour as illustrated in FIG. 4B. In some embodiments, the zeroth order is removed as it is common in DO maps, and half of the peaks (e.g., by rotational symmetry) are extracted considering the centrosymmetric characteristic of Fourier transform. In some embodiments, peak contours with a size larger than a certain number of pixels are classified as continuous peaks. This size limit of the contour area can be adjusted, for example, it can be set as 3 pixels. In some embodiments, other peaks with smaller contour area are classified as discrete peaks.

Referring to FIG. 2, in some embodiments, system 200 further comprises DO grouping component 230 to group the peaks extracted and classified by extraction subcomponent 330 as disclosed above. In some embodiments, during the grouping process, the peaks are grouped by applying one or more grouping criteria (e.g., coverage criteria used to determine whether one peak can cover another). The peaks covering one another according to the grouping criteria may be considered similar enough to be placed in the same group. In some embodiments, a plurality of grouping criteria (e.g., coverage criteria), e.g., 3 criteria as disclosed below, may be applied to the peaks simultaneously, sequentially, or in any suitable combination, to obtain coverage relationship between the peaks. For example, the extracted peaks are divided into multiple pairs of peaks or any other suitable number of sets for comparison. The multiple grouping criteria may be applied to respective pairs of peaks to determine, for each pair of peaks, whether one peak can be covered by the other peak in the same pair, so as to place the two peaks within a same group. All extracted patterns can be evaluated using the grouping criteria as disclosed below. After the grouping process, one representative pattern can be selected from each group, so as to reduce the number of patterns used for inspection or optimization and to improve the SMO productivity.

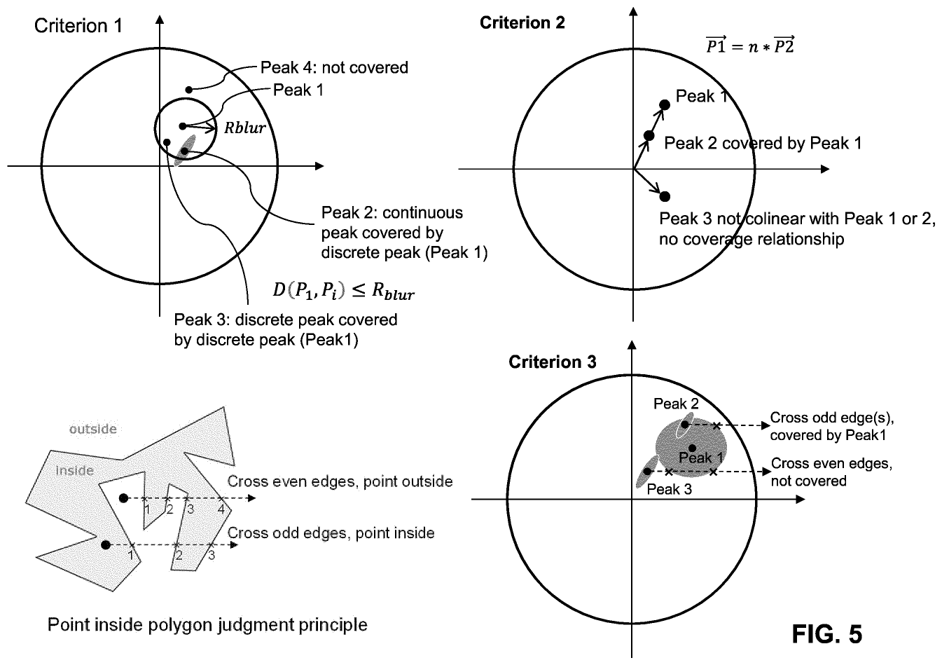

FIG. 5 illustrates example grouping criteria used for grouping the peaks in DO maps, consistent with embodiments of the present disclosure. In some embodiments, under the first criterion, for a pair of discrete peaks, or a pair of discrete peak and continuous peak, a distance D (P₁, Pᵢ) between the peak centers of the two peaks P₁ and Pᵢ can be compared against a predetermined tolerance threshold R_{blur}. For example, as shown as examples of applying criterion 1 in FIG. 5, when D (P₁, Pᵢ) R_{blur}, (i=2, 3, 4, etc.), it is determined that there is a coverage relationship between the two peaks P₁ and Pᵢ (e.g., one of the two peaks can be covered by the other). When D (P₁, Pᵢ)>R_{blur}, it is determined that there is no coverage relationship between the two peaks P₁ and Pᵢ. For example, as shown in FIG. 5, the distance D (P₁, P₂) between the discrete peak Peak 1 and continuous peak Peak 2, and the distance D (P₁, P₃) between the discrete peak Peak 1 and discrete peak Peak 3 is respectively shorter than the tolerance threshold R_{blur}. That is, the peak centers of Peak 2 and Peak 3 are included within a circle centered at the peak center of Peak 1 and with a radius of the tolerance threshold R_{blur}. As a result, it is determined Peak 1 can cover Peak 2 and Peak 3 respectively. On the other hand, the distance D (P₁, P₄) between the discrete peak Peak 1 and discrete peak Peak 4 is larger than the tolerance threshold R_{blur}. Accordingly, Peak 1 cannot cover Peak 4. In some embodiments, a restriction is considered for the first criterion where a continuous peak cannot cover a discrete peak, because discrete peaks generally have larger intensity than continuous peaks. On the other hand, a discrete peak can cover a continuous peak or another discrete peak.

In some embodiments, R_{blur} is set based on the source rendering effect in SMO. For example, R_{blur} can be set as 3 DO map pixels (e.g., for 201×201 pixels DO map, wherein 3 pixels=0.03 sigma). A pair of peaks whose center distance is smaller than the R_{blur}, e.g., 3 pixels, are considered to cover each other and can be placed within the same group. R_{blur} can be predetermined or set by a user. In some embodiments, R_{blur} is a parameter dependent on the illuminator of the scanner tool. For example, R_{blur} can be related to the limit of the resolution defined by the illuminator, such as half the pixel unit defined in SMO pupil map. The peaks that are closer to each other than R_{blur} may not be distinguished on the SMO pupil map, and thus can be considered to cover each other in the same group.

In some embodiments, under the second criterion, for a pair of discrete peaks, if two peaks are colinear and with one frequency being an integer multiple of the other frequency (e.g., for harmonic peaks), e.g., \vec{P₁}=n*\vec{P₂}, the peak with the larger frequency covers the other peak with the smaller frequency, e.g., P₁ covers P₂ as shown as an example of application of criterion 2 in FIG. 5. In some embodiments, the second criterion can be applied to a pattern with added sub-resolution assistant features (SFAR), such as assistant bars for enhancing the process window of isolated features, where the pattern with SRAF is considered to be covered by the pattern without adding SRAF. This is because patterns with lower DO frequency have a larger pitch, and SRAF generated after Optical Proximity Correction (OPC) can increase the DO frequency (e.g., with smaller pitch) by multiple integer times. In some embodiments, the second criterion can be applied to peaks situated colinear to each other, and can be applied to peaks at any direction without limitation. That is, instead of being limited to peaks situated only at certain directions, such as only x or y direction, only four directions (e.g., orthogonal), or only eight directions, the method disclosed herein can be applied to peaks located at any direction, such as an arbitrary direction, or an unlimited direction. As such, the present disclosure can be applied to patterns with any orientation.

In some embodiments, under the third criterion, for a pair of continuous peaks, it is determined whether the center of one peak (e.g., Peak 2 or Peak 3 in FIG. 5) is included in the contour of the other peak (e.g., Peak 1) in the respective pair. In some embodiments, the raw peak contour can be considered at all directions, and the actual (e.g., precise) peak contour can be used without approximation. A suitable image processing method, such as a judgment principle for determining whether a point is located inside a polygon, can be used. For example, as shown in the illustration of the “point inside polygon judgment principle” diagram in FIG. 5, to determine whether a point falls inside a polygon, a ray is drawn from the point in any direction. If the point-cross-polygon edge number is odd (e.g., 3 in FIG. 5), the point is inside. If the number is even (e.g., 4 in FIG. 5), the point is outside. In some embodiments, the third criterion can be applied to peaks at any direction, e.g., an unlimited direction, or an arbitrary direction, without limitation.

As shown as examples of applying the third criterion and the judgment principle in FIG. 5, in determining whether the peak center falls inside a peak contour (e.g., using a polygon contour as an example), a ray can be drawn from the peak center of Peak 2 or Peak 3 in any direction (e.g., along any direction without limitation). The times of the ray intersecting with the polygon contour of Peak 1 is counted. If the number of times the ray intersects with one or more edges of the polygon contour of Peak 1 is an odd number (e.g., 1 time), it is determined that the peak center of Peak 2 is inside the peak contour of Peak 1, and Peak 1 covers Peak 2. If this number is even (e.g., 2 times), it is determined that the peak center of Peak 3 is outside the peak contour of Peak 1, and Peak 1 does not cover Peak 3.

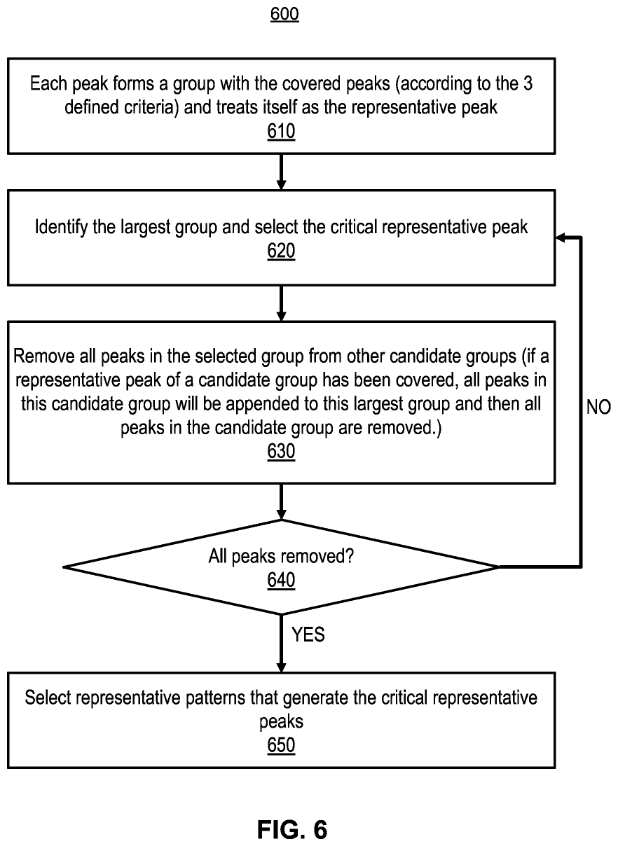

Referring to FIG. 2, in some embodiments, system 200 further comprises pattern selection component 240 to select critical patterns based on the critical representative peaks. FIG. 6 is a process flowchart representing an example process 600 of pattern selection, in accordance with some embodiments of the present disclosure. In some embodiments, one or more steps are performed by one or more components of pattern selection component 240 in FIG. 2.

In step 610, groups for respective peaks can be formed, and each peak is treated as a representative peak of the corresponding group. Then, for each group, the coverage criteria, e.g., according to 3 coverage criteria in FIG. 5, can be applied, such that other peaks covered by a respective representative peak can be placed into the same group (associated with the representative peak). Accordingly, all peaks covered by the representative peak will be placed in the corresponding group. In step 620, the largest group of all existing groups (e.g., with the largest number of peaks) can be identified, and the critical representative peak can be selected. In step 630, duplicate peaks covered in multiple groups can be merged. In some embodiments, after the grouping process in step 610, there are peaks that can be grouped into different groups as duplicate peaks. In some embodiments, the pattern selection can be performed to select the least number of patterns that can cover all diffraction order (DO) signatures or as many DO signatures as possible (e.g., all peaks or as many peaks as possible). Accordingly, the process may start from the largest group (e.g., having the largest number of peaks) to remove the duplicate peaks included in other groups. For example, if a representative peak of a corresponding candidate group has been covered by other peak(s), such as being covered by a peak included in the largest group. Then all peaks in this candidate group can be added to this largest group, and this candidate group can be removed entirely. Furthermore, duplicate peaks within a certain group can also be merged. Next, in step 640, it is determined whether all peaks have been removed from other groups (e.g., does any other group include peaks after the removal?). If there are peaks that have not been removed (“NO”), process 600 proceeds to step 620 to identify the next largest group and repeat steps 620, 630 and 640. If all peaks have been removed (“YES”), process 600 proceeds to step 650 where the critical patterns corresponding to (e.g., that generate) the critical representative peaks are selected. During the pattern selection, the critical representative peaks may include peaks that cover most other peaks, or peaks that are unique and not covered by any other peaks. After the pattern selection, patterns corresponding to the above critical representative peaks are selected as critical patterns.

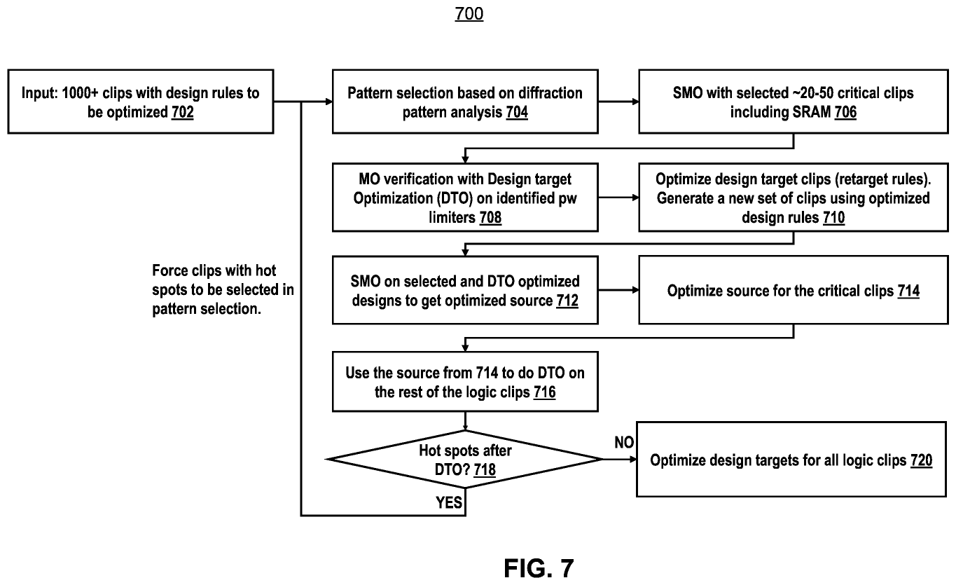

FIG. 7 is a process flowchart representing an example process 700 of SMO design target optimization, in accordance with some embodiments of the present disclosure. In some embodiments, one or more steps are performed by SMO design target optimization component 250 in FIG. 2.

In some embodiments, steps 702 and 704 are substantially similar to the processes performed by one or more components of system 200, such as DO map generation component 210, DO map processing component 220, DO grouping component 230, or pattern selection component 240, as disclosed herein. For example, in step 702, a set of clips, e.g., over 1000 clips, with original design rules are obtained for optimization in process 700. In step 704, a subset of critical patterns including critical representative peaks can be intelligently selected from the set of clips as disclosed herein. In step 706, the selected critical patterns (e.g., obtained in step 650 of FIG. 6), e.g., 20-50 critical clips including SRAM features selected from the set of more than 1000 clips, may be performed with SMO. In some embodiments, source and mask are treated as variables in step 706 during the optimization, to obtain an optimized source and optimized mask designs.

In step 708, mask optimization (MO) verification can be performed. It is verified that the performance (e.g., process window, depth of focus (DOF)) based on the selected critical clips are substantially similar (or not substantially inferior) to the performance based on the original set of more than 1000 clips. Further, one or more limiters, corresponding to one or more features including but not limited to edge placement error (EPE), pattern placement error (PPE), CDs, or pitches under the old design rules, that limit the improvement of performance can be identified. In some embodiments, MO includes optical proximity correction (OPC) and sub-resolution assist feature (SRAF) technique, and is performed on all patterns to obtain process window, mask error enhancement factor (MEEF) and mask complexity.

In step 710, the layout retarget rules can be optimized on the identified limiters to enhance lithography image performance. For example, for SRAM features, variables can be assigned to different limiters, such as edge placement error (EPE), pattern placement error (PPE), CDs, or pitches, identified in step 708, and these variables can be optimized in combination to obtain an improved performance based on the process window. The optimized variables of limiters correspond to the new and optimized layout retarget rules. In some embodiments, the optimized layout retarget rules obtained in step 710 can be applied to original design targets in step 708, e.g., all clips, to generate a new set of clips in step 710.

In step 712, critical representative clips can be selected, and another SMO process can be performed on the selected critical patterns and the new set of clips (e.g., design target optimized (DTO) clips obtained in step 710 based on the new optimized layout retarget rules) to obtain optimized source. In some embodiments in step 712, source (e.g., illumination source), mask (e.g., mask design layout), and target (e.g., layout retarget rules) can be co-optimized. In step 714, the source and mask for the critical clips can be optimized, based on the target optimized in step 712. In step 716, the source optimized in step 714 can be used to perform DTO, e.g., to optimize mask and target, on the rest of the logic clips. In step 718, it is determined whether there are still hot spots after the DTO. For example, it is determined whether one or more hot spots can be identified in the plurality of patterns on the design layout. If there are no more hot spots (e.g., “NO”), the design targets with the new layout retarget rules can be used to optimize all logic clips (e.g., full chip optimization) in step 720. If there are still hot spots (e.g., “YES”), process 700 proceeds to step 704 to perform pattern selection based on DO maps. Steps 704-718 as disclosed herein are further repeated until no more than a predetermined threshold number of hot spots can be identified at step 718. In some embodiments, after the full chip optimization based on the new layout retarget rules can demonstrate improvement in the performance, e.g., window process, DOF, over the previous performance.

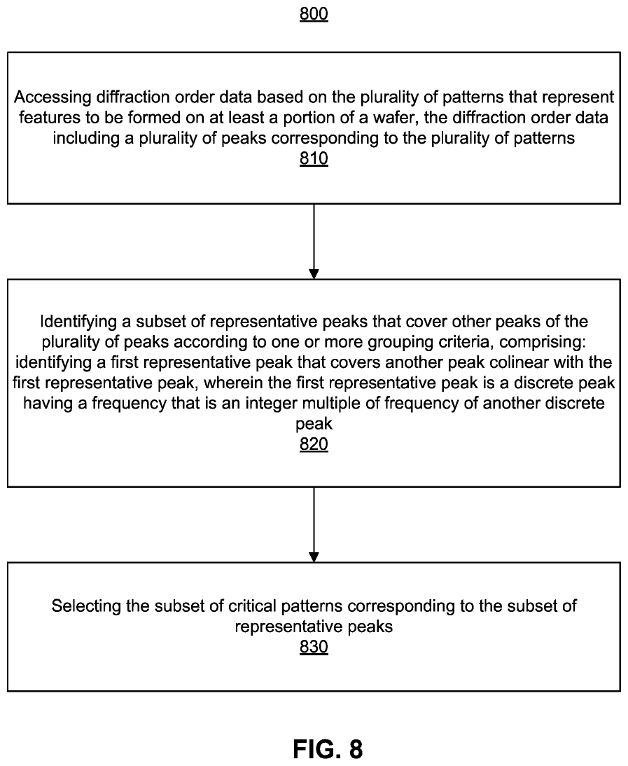

FIG. 8 is a process flowchart representing an example method 800 for selecting a subset of critical patterns from a plurality of patterns of a design layout, in accordance with some embodiments of the present disclosure. In some embodiments, one or more steps are performed by one or more components of system 200 in FIG. 2, one or more components of system 300 in FIG. 3.

In step 810, diffraction order data, such as a plurality of diffraction order maps or in any other suitable format or representation, can be accessed. In some embodiments, the diffraction order data is obtained based on the plurality of patterns that represent features to be formed on at least a portion of a wafer. The diffraction order data or information can be generated in any suitable manner, algorithm, method, etc., without departing from the scope of the present disclosure. The diffraction order data or information can be provided by a separate module or software product that is independent from the system as disclosed herein. The diffraction order data or information can also be generated by a component or module of the system as disclosed herein. In some embodiments, the plurality of diffraction order maps include a plurality of peaks corresponding to the plurality of patterns. In some embodiments, as shown in FIG. 4A, DO map generation component 210 can perform Fourier Transform to the plurality of patterns to generate, respectively, the plurality of DO maps in a frequency domain. In some embodiments, the plurality of patterns include periodic patterns or non-periodic patterns. In some embodiments, the plurality of DO maps are processed to identify the plurality of peaks. For example, as shown in FIGS. 3 and 4A-4B, normalization and grayscale subcomponent 310 normalizes and assigns grayscale values to the DO maps. Binarization subcomponent 320 can binarize the DO maps to sharpen the contours of the images. Extraction subcomponent 330 can extract the peak centers and peak contours as shown in FIGS. 4A-4B. The peaks can be classified into discrete peaks and continuous peaks. In the present disclosure, the peaks at arbitrary directions without any limitation are being considered.

In step 820, a subset of representative peaks that cover other peaks of the plurality of peaks can be identified by DO grouping component 230 according to one or more grouping criteria. In some embodiments, the one or more grouping criteria are associated with evaluating relative locations of the plurality of peaks in the plurality of DO maps. The plurality of peaks are divided into multiple pairs. As shown in FIG. 5, in some embodiments, for a pair of discrete peaks, a first representative peak (e.g., discrete peak 1 under criterion 2) can be identified to cover one or more other peaks (e.g., discrete peaks) colinear with the first representative peak, and the first representative peak having a frequency that is integer multiples of frequencies of the one or more other peaks (e.g., harmonic peaks). In some embodiments, for a pair of discrete peaks, or a pair of discrete peak and continuous peak, a second representative peak (e.g., peak 1 under criterion 1) can be identified to cover one or more other peaks whose peak centers are located within a predetermined distance (e.g., R_{blur}) from a peak center of the second representative peak. In some embodiments, for a pair of continuous peaks, a third representative peak (e.g., peak 1 under criterion 3) can be identified to cover one or more other peaks with peak centers located within a peak contour of the third representative peak.

In step 830, the subset of critical patterns can be selected by pattern selection component 240 based on the subset of representative peaks selected in step 820. In some embodiments, the subset of critical patterns are provided for use in at least one of optical proximity correction (OPC), defect inspection, defect prediction, or source mask optimization (SMO).

In some embodiments, a process of SMO design target optimization can be performed by SMO design target optimization component 250 to the selected critical patterns obtained in step 830. For example, limiters under the old design rule can be identified, and the design rule can be adjusted accordingly, to improve the lithography image performance.

By using the method disclosed in the present disclosure, any type of features with any patterns, including 2-D non-periodic patterns, can be effectively and accurately processed and grouped to identify the representative peaks for the non-periodic patterns. Further, the DO peaks in any directions or any arbitrary directions are considered without any limitation on peak directions (e.g., only x and y directions, or eight directions in conventional methods) or pattern orientations. Additionally, various criteria are used simultaneously for determining the coverage relationship between DO peaks. As a result, the accuracy of pattern selection can be improved, and fewer critical patterns are selected compared to the conventional method while sufficiently covering the patterns on the whole chip to deliver similar performance as the conventional method. Accordingly, the run-time can be reduced (e.g., by saving 30%-60% runtime compared to the conventional method) and the productivity can be improved without compromising the performance. For example, it can be time-consuming to run SMO on 2-D non-periodic patterns with complex patterns. By accurately analyzing and grouping the 2-D non-periodic patterns as disclosed herein, the SMO runtime can be significantly reduced. Additionally, the target pattern optimization disclosed herein include performing a second optimization to the selected patterns, so as to further improve the lithography performance gain and reduce the SMO turnaround time.

A non-transitory computer readable medium may be provided that stores instructions for a processor of a system (e.g., system 200 of FIG. 2), or a component (e.g., component 220 of FIG. 3) to carry out, among other things, DO map generation, DO map processing, DO grouping, pattern grouping, peak selection, pattern selection, SMO, SMO design target optimization, mask optimization, source optimization, image inspection, image acquisition, image transformation, image processing, image comparison, stage positioning, beam focusing, electric field adjustment, beam bending, condenser lens adjusting, activating charged-particle source, and beam deflecting, etc., such as described above regarding process 600, process 700, or method 800. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:

1. A method of selecting a subset of critical patterns from a plurality of patterns of a design layout, the method comprising:
accessing diffraction order data based on the plurality of patterns that represent features to be formed on at least a portion of a wafer, the diffraction order data including a plurality of peaks corresponding to the plurality of patterns;
identifying a subset of representative peaks from the plurality of peaks according to one or more grouping criteria, comprising:
   identifying a first representative peak of the subset of representative peaks that covers another peak colinear with the first representative peak, wherein the first representative peak is a discrete peak having a frequency that is an integer multiple of frequency of another discrete peak; and selecting the subset of critical patterns corresponding to the subset of representative peaks.

2. The method of clause 1, further comprising:
generating the diffraction order data including a plurality of diffraction order maps; and performing Fourier Transform on the plurality of patterns to generate, respectively, the plurality of diffraction order maps in a frequency domain.

3. The method of any one of clauses 1-2, wherein the plurality of patterns includes one or more non-periodic patterns.

4. The method of any one of clauses 2-3, further comprising:
processing the plurality of diffraction order maps via normalization and grayscaling.

5. The method of clause 4, further comprising:
processing the plurality of diffraction order maps via binarization to identify the plurality of peaks.

6. The method of any one of clauses 1-5, further comprising:
extracting peak centers and peak contours of the plurality of peaks; and classifying the plurality of peaks into discrete peaks and continuous peaks.

7. The method of any one of clauses 2-6, wherein the plurality of peaks are located at various directions on the diffraction order maps without limitation.

8. The method of any one of clauses 1-7, wherein identifying the subset of representative peaks from the plurality of peaks according to one or more grouping criteria further comprises:
identifying a second representative peak of the subset of representative peaks that covers one or more other peaks with respective peak centers that are located within a predetermined distance from a peak center of the first representative peak, wherein the second representative peak is a discrete peak, and the one or more peaks covered by the second representative peak include a discrete peak or a continuous peak.

9. The method of any one of clauses 1-8, wherein identifying the subset of representative peaks from the plurality of peaks according to one or more grouping criteria comprises:
identifying a third representative peak of the subset of representative peaks that covers one or more other peaks with peak centers located within a peak contour of the third representative peak, wherein the third representative peak is a continuous peak and located in an unlimited direction, and the one or more peaks covered by the third representative peak are continuous.

10. The method of any one of clauses 1-9, wherein the peak contour is an actual contour without approximation.

11. The method of any one of clauses 1-10, further comprising:
performing a first SMO to the subset of critical patterns;
performing a first mask optimization verification to identify one or more feature limiters; optimizing layout retarget rules based on the identified one or more feature limiters and generating a set of clips based on the optimized layout retarget rules;
performing a second SMO to the subset of critical patterns and the generated set of clips to obtain optimized source;
performing a second mask optimization verification to the plurality of patterns with the optimized source and optimized targets according to the adjusted layout retarget rules;
determining whether one or more hot spots are identified in the design layout; and
in accordance with determining that no hot spot is identified, adopting the optimized source and the optimized layout retarget rules for full chip design.

12. The method of any one of clauses 1-11, wherein the design layout is in Graphic Database System (GDS) format, Graphic Database System II (GDS II) format, Open Artwork System Interchange Standard (OASIS) format, or Caltech Intermediate Format (CIF).

13. The method of any one of clauses 1-12, wherein the subset of critical patterns are provided for use in at least one of optical proximity correction (OPC), defect inspection, defect prediction, or source mask optimization (SMO).

14. A system comprising:
a memory storing a set of instructions; and
at least one processor configured to execute the set of instructions to cause the system to perform:
   accessing diffraction order data based on the plurality of patterns that represent features to be formed on at least a portion of a wafer, the diffraction order data including a plurality of peaks corresponding to the plurality of patterns;
   identifying a subset of representative peaks from the plurality of peaks according to one or more grouping criteria, comprising:
      identifying a first representative peak of the subset of representative peaks that covers another peak colinear with the first representative peak, wherein the first representative peak is a discrete peak having a frequency that is an integer multiple of frequency of another discrete peak; and
   selecting the subset of critical patterns corresponding to the subset of representative peaks.

15. The system of clause 14, wherein the at least one processor is further configured to cause the system to perform:
generating the diffraction order data including a plurality of diffraction order maps;
performing Fourier Transform on the plurality of patterns to generate, respectively, the plurality of diffraction order maps in a frequency domain.

16. The system of any one of clauses 14-15, wherein the plurality of patterns includes one or more non-periodic patterns.

17. The system of any one of clauses 15-16, wherein the at least one processor is further configured to cause the system to perform:
processing the plurality of diffraction order maps via normalization and grayscaling.

18. The system of clause 17, wherein the at least one processor is further configured to cause the system to perform:
processing the plurality of diffraction order maps via binarization to identify the plurality of peaks.

19. The system of any one of clauses 14-18, wherein the at least one processor is further configured to cause the system to perform:
extracting peak centers and peak contours of the plurality of peaks; and classifying the plurality of peaks into discrete peaks and continuous peaks.

20. The system of any one of clauses 15-19, wherein the plurality of peaks are located at various directions on the diffraction order maps without limitation.

21. The system of any one of clauses 14-20, wherein identifying the subset of representative peaks from the plurality of peaks according to one or more grouping criteria comprises:
identifying a second representative peak of the subset of representative peaks that covers one or more other peaks with respective peak centers that are located within a predetermined distance from a peak center of the first representative peak, wherein the second representative peak is a discrete peak, and the one or more peaks covered by the second representative peak include a discrete peak or a continuous peak.

22. The system of any one of clauses 14-21, wherein identifying the subset of representative peaks from the plurality of peaks according to one or more grouping criteria comprises:
identifying a third representative peak of the subset of representative peaks that covers one or more other peaks with peak centers located within a peak contour of the third representative peak, wherein the third representative peak is a continuous peak and located in an unlimited direction, and the one or more peaks covered by the third representative peak are continuous.

23. The system of any one of clauses 14-22, wherein the peak contour is an actual contour without approximation.

24. The system of any one of clauses 14-23, wherein the at least one processor is further configured to cause the system to perform:
performing a first SMO to the subset of critical patterns;
performing a first mask optimization verification to identify one or more feature limiters;
optimizing layout retarget rules based on the identified one or more feature limiters and generating a set of clips based on the optimized layout retarget rules; and
performing a second SMO to the subset of critical patterns and the generated set of clips to obtain optimized source;
performing a second mask optimization verification to the plurality of patterns with the optimized source and optimized target according to the adjusted layout retarget rules;
determining whether one or more hot spots are identified in the design layout; and
in accordance with determining that no hot spot is identified, adopting the optimized source and the optimized layout retarget rules for full chip design.

25. The system of any one of clauses 14-24, wherein the design layout is in Graphic Database System (GDS) format, Graphic Database System II (GDS II) format, Open Artwork System Interchange Standard (OASIS) format, or Caltech Intermediate Format (CIF).

26. The system of any one of clauses 14-25, wherein the subset of critical patterns are provided for use in at least one of optical proximity correction (OPC), defect inspection, defect prediction, or source mask optimization (SMO).

27. A non-transitory computer readable medium that stores a set of instructions that is executable by at least one processor of a system to cause the system to perform a method of selecting a subset of critical patterns from a plurality of patterns of a design layout, the method comprising:
accessing diffraction order data based on the plurality of patterns that represent features to be formed on at least a portion of a wafer, the diffraction order data including a plurality of peaks corresponding to the plurality of patterns;
identifying a subset of representative peaks from the plurality of peaks according to one or more grouping criteria, comprising:
   identifying a first representative peak of the subset of representative peaks that covers another peak colinear with the first representative peak, wherein the first representative peak is a discrete peak having a frequency that is an integer multiple of frequency of another discrete peak; and
selecting the subset of critical patterns corresponding to the subset of representative peaks.

28. The non-transitory computer readable medium of clause 27, wherein the set of instructions that is executable by the at least one processor of the system to cause the system to further perform:
generating the diffraction order data including a plurality of diffraction order maps; and
performing Fourier Transform on the plurality of patterns to generate, respectively, the plurality of diffraction order maps in a frequency domain.

29. The non-transitory computer readable medium of any one of clauses 27-28, wherein the plurality of patterns includes one or more non-periodic patterns.

30. The non-transitory computer readable medium of any one of clauses 28-29, wherein the set of instructions that is executable by the at least one processor of the system to cause the system to further perform:
processing the plurality of diffraction order maps via normalization and grayscaling.

31. The non-transitory computer readable medium of clause 30, wherein the set of instructions that is executable by the at least one processor of the system to cause the system to further perform:
processing the plurality of diffraction order maps via binarization to identify the plurality of peaks.

32. The non-transitory computer readable medium of any one of clauses 28-31, wherein the set of instructions that is executable by the at least one processor of the system to cause the system to further perform:
extracting peak centers and peak contours of the plurality of peaks; and
classifying the plurality of peaks into discrete peaks and continuous peaks.

33. The non-transitory computer readable medium of any one of clauses 27-32, wherein the plurality of peaks are located at various directions on the diffraction order maps without limitation.

34. The non-transitory computer readable medium of any one of clauses 27-33, wherein identifying the subset of representative peaks from the plurality of peaks according to one or more grouping criteria comprises:
identifying a second representative peak of the subset of representative peaks that covers one or more other peaks with respective peak centers that are located within a predetermined distance from a peak center of the first representative peak, wherein the second representative peak is a discrete peak, and the one or more peaks covered by the second representative peak include a discrete peak or a continuous peak.

35. The non-transitory computer readable medium of any one of clauses 27-34, wherein identifying the subset of representative peaks from the plurality of peaks according to one or more grouping criteria comprises:
identifying a third representative peak of the subset of representative peaks that covers one or more other peaks with peak centers located within a peak contour of the third representative peak, wherein the third representative peak is a continuous peak and located in an unlimited direction, and the one or more peaks covered by the third representative peak are continuous.

36. The non-transitory computer readable medium of any one of clauses 27-35, wherein the peak contour is an actual contour without approximation.

37. The non-transitory computer readable medium of any one of clauses 27-36, wherein the set of instructions that is executable by the at least one processor of the system to cause the system to further perform:
performing a first SMO to the subset of critical patterns;
performing a first mask optimization verification to identify one or more feature limiters;
optimizing layout retarget rules based on the identified one or more feature limiters and generating a set of clips based on the optimized layout retarget rules; and
performing a second SMO to the subset of critical patterns and the generated set of clips to obtain optimized source;
performing a second mask optimization verification to the plurality of patterns with the optimized source and optimized target according to the adjusted layout retarget rules;
determining whether one or more hot spots are identified in the design layout; and
in accordance with determining that no hot spot is identified, adopting the optimized source and the optimized layout retarget rules for full chip design.

38. The non-transitory computer readable medium of any one of clauses 27-37, wherein the design layout is in Graphic Database System (GDS) format, Graphic Database System II (GDS II) format, Open Artwork System Interchange Standard (OASIS) format, or Caltech Intermediate Format (CIF).

39. The non-transitory computer readable medium of any one of clauses 27-38, wherein the subset of critical patterns are provided for use in at least one of optical proximity correction (OPC), defect inspection, defect prediction, or source mask optimization (SMO).

40. A method of performing a design target optimization, the method comprising:
performing a first source mask optimization (SMO) to a subset of critical patterns of a plurality of patterns of a design layout;
optimizing layout retarget rules based on one or more feature limiters;
generating a set of clips based on the optimized layout retarget rules; and
performing a second SMO to the subset of critical patterns and the generated set of clips to obtain optimized source.

41. The method of clause 40, further comprising:
performing a first mask optimization verification to identify the one or more feature limiters.

42. The method of clause 41, further comprising:
performing a second mask optimization verification to the plurality of patterns with the optimized source and optimized targets according to the optimized layout retarget rules.

43. The method of clause 42, further comprising:
determining whether one or more hot spots are identified in the design layout; and
in accordance with determining that no hot spot is identified, adopting the optimized source and the optimized layout retarget rules for full chip design.

44. The method of any one of clauses 40-43, further comprising selecting the subset of critical patterns of the plurality of patterns, comprising:
accessing diffraction order data including a plurality of peaks corresponding to the plurality of patterns;
identifying a subset of representative peaks from the plurality of peaks according to one or more grouping criteria; and
selecting the subset of critical patterns corresponding to the subset of representative peaks.

45. The method of clause 44, wherein identifying the subset of representative peaks from the plurality of peaks according to one or more grouping criteria further comprises:
identifying a first representative peak of the subset of representative peaks that covers another peak colinear with the first representative peak, wherein the first representative peak is a discrete peak having a frequency that is an integer multiple of frequency of another discrete peak.

46. The method of clause 44, wherein identifying the subset of representative peaks from the plurality of peaks according to one or more grouping criteria further comprises:
identifying a second representative peak of the subset of representative peaks that covers one or more other peaks with respective peak centers that are located within a predetermined distance from a peak center of the first representative peak, wherein the second representative peak is a discrete peak, and the one or more peaks covered by the second representative peak include a discrete peak or a continuous peak.

47. The method of clause 44, wherein identifying the subset of representative peaks from the plurality of peaks according to one or more grouping criteria further comprises:
identifying a third representative peak of the subset of representative peaks that covers one or more other peaks with peak centers located within a peak contour of the third representative peak, wherein the third representative peak is a continuous peak and located in an unlimited direction, and the one or more peaks covered by the third representative peak are continuous.

48. A system comprising:
a memory storing a set of instructions; and
at least one processor configured to execute the set of instructions to cause the system to perform:
   performing a first source mask optimization (SMO) to a subset of critical patterns of a plurality of patterns of a design layout;
   optimizing layout retarget rules based on one or more feature limiters;
   generating a set of clips based on the optimized layout retarget rules; and
   performing a second SMO to the subset of critical patterns and the generated set of clips to obtain optimized source.

49. The system of clause 48, wherein the at least one processor is further configured to cause the system to perform:
performing a first mask optimization verification to identify the one or more feature limiters.

50. The system of clause 49, wherein the at least one processor is further configured to cause the system to perform:
performing a second mask optimization verification to the plurality of patterns with the optimized source and optimized targets according to the optimized layout retarget rules.

51. The system of clause 50, wherein the at least one processor is further configured to cause the system to perform:
determining whether one or more hot spots are identified in the design layout; and
in accordance with determining that no hot spot is identified, adopting the optimized source and the optimized layout retarget rules for full chip design.

52. The system of any one of clauses 48-51, wherein the at least one processor is further configured to cause the system to perform:
selecting the subset of critical patterns of the plurality of patterns, comprising:
   accessing diffraction order data including a plurality of peaks corresponding to the plurality of patterns;
   identifying a subset of representative peaks from the plurality of peaks according to one or more grouping criteria; and
   selecting the subset of critical patterns corresponding to the subset of representative peaks.

53. The system of clause 52, wherein identifying the subset of representative peaks from the plurality of peaks according to one or more grouping criteria further comprises:
identifying a first representative peak of the subset of representative peaks that covers another peak colinear with the first representative peak, wherein the first representative peak is a discrete peak having a frequency that is an integer multiple of frequency of another discrete peak.

54. The system of clause 52, wherein identifying the subset of representative peaks from the plurality of peaks according to one or more grouping criteria further comprises:
identifying a second representative peak of the subset of representative peaks that covers one or more other peaks with respective peak centers that are located within a predetermined distance from a peak center of the first representative peak, wherein the second representative peak is a discrete peak, and the one or more peaks covered by the second representative peak include a discrete peak or a continuous peak.

55. The system of clause 52, wherein identifying the subset of representative peaks from the plurality of peaks according to one or more grouping criteria further comprises:
identifying a third representative peak of the subset of representative peaks that covers one or more other peaks with peak centers located within a peak contour of the third representative peak, wherein the third representative peak is a continuous peak and located in an unlimited direction, and the one or more peaks covered by the third representative peak are continuous.

56. A non-transitory computer readable medium that stores a set of instructions that is executable by at least one processor of a system to cause the system to perform a method of performing a design target optimization, the method comprising:
performing a first source mask optimization (SMO) to a subset of critical patterns of a plurality of patterns of a design layout;
optimizing layout retarget rules based on one or more feature limiters;
generating a set of clips based on the optimized layout retarget rules; and performing a second SMO to the subset of critical patterns and the generated set of clips to obtain optimized source.

57. The non-transitory computer readable medium of clause 56, wherein the set of instructions that is executable by the at least one processor of the system to cause the system to further perform:
performing a first mask optimization verification to identify the one or more feature limiters.

58. The non-transitory computer readable medium of clause 57, wherein the set of instructions that is executable by the at least one processor of the system to cause the system to further perform:
performing a second mask optimization verification to the plurality of patterns with the optimized source and optimized targets according to the optimized layout retarget rules.

59. The non-transitory computer readable medium of clause 58, wherein the set of instructions that is executable by the at least one processor of the system to cause the system to further perform:
determining whether one or more hot spots are identified in the design layout; and
in accordance with determining that no hot spot is identified, adopting the optimized source and the optimized layout retarget rules for full chip design.

60. The non-transitory computer readable medium of any one of clauses 56-59, wherein the set of instructions that is executable by the at least one processor of the system to cause the system to further perform:
selecting the subset of critical patterns of the plurality of patterns, comprising:
   accessing diffraction order data including a plurality of peaks corresponding to the plurality of patterns;
   identifying a subset of representative peaks from the plurality of peaks according to one or more grouping criteria; and
   selecting the subset of critical patterns corresponding to the subset of representative peaks.

61. The non-transitory computer readable medium of clause 60, wherein identifying the subset of representative peaks from the plurality of peaks according to one or more grouping criteria further comprises:
identifying a first representative peak of the subset of representative peaks that covers another peak colinear with the first representative peak, wherein the first representative peak is a discrete peak having a frequency that is an integer multiple of frequency of another discrete peak.

62. The non-transitory computer readable medium of clause 60, wherein identifying the subset of representative peaks from the plurality of peaks according to one or more grouping criteria further comprises:
identifying a second representative peak of the subset of representative peaks that covers one or more other peaks with respective peak centers that are located within a predetermined distance from a peak center of the first representative peak, wherein the second representative peak is a discrete peak, and the one or more peaks covered by the second representative peak include a discrete peak or a continuous peak.

63. The non-transitory computer readable medium of clause 60, wherein identifying the subset of representative peaks from the plurality of peaks according to one or more grouping criteria further comprises:
identifying a third representative peak of the subset of representative peaks that covers one or more other peaks with peak centers located within a peak contour of the third representative peak, wherein the third representative peak is a continuous peak and located in an unlimited direction, and the one or more peaks covered by the third representative peak are continuous.

The block diagrams in the figures illustrate the architecture, functionality, and operation of possible implementations of systems, methods, and computer hardware/software products according to various exemplary embodiments of the present disclosure. In this regard, each block in a schematic diagram may represent certain arithmetical or logical operation processing that may be implemented using hardware such as an electronic circuit. Blocks may also represent a module, a segment, or a portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A method of selecting a subset of critical patterns from a plurality of patterns of a design layout, the method comprising:
accessing diffraction order data based on the plurality of patterns that represent features to be formed on at least a portion of a substrate, the diffraction order data including a plurality of peaks corresponding to the plurality of patterns;
identifying, by a hardware computer system, a subset of representative peaks from the plurality of peaks according to one or more grouping criteria, the identifying comprising identifying a first representative peak of the subset of representative peaks that covers another peak colinear with the first representative peak, wherein the first representative peak is a discrete peak having a frequency that is an integer multiple of frequency of another discrete peak; and
selecting the subset of critical patterns corresponding to the subset of representative peaks.

2. The method of claim 1, further comprising performing a Fourier transform on the plurality of patterns to generate, respectively, the diffraction order data.

3. The method of claim 1, wherein the diffraction order data represents a plurality of diffraction order maps.

4. The method of claim 1, wherein the plurality of patterns includes one or more non-periodic patterns.

5. The method of claim 1, further comprising processing the diffraction order data via normalization and grayscaling.

6. The method of claim 5, further comprising processing the diffraction order data via binarization to identify the plurality of peaks.

7. The method of claim 1, further comprising:
extracting peak centers and peak contours of the plurality of peaks; and
classifying the plurality of peaks into discrete peaks and continuous peaks.

8. The method of claim 3, wherein the plurality of peaks are located at arbitrary directions on the diffraction order maps.

9. The method of claim 1, wherein identifying the subset of representative peaks from the plurality of peaks according to one or more grouping criteria further comprises identifying a second representative peak of the subset of representative peaks that covers one or more other peaks with respective peak centers that are located within a predetermined distance from a peak center of the first representative peak, wherein the second representative peak is a discrete peak, and the one or more peaks covered by the second representative peak include a discrete peak or a continuous peak.

10. The method of claim 1, wherein identifying the subset of representative peaks from the plurality of peaks according to one or more grouping criteria further comprises identifying a third representative peak of the subset of representative peaks that covers one or more other peaks with respective peak centers located within a peak contour of the third representative peak, wherein the third representative peak is a continuous peak and located in an unlimited direction, and the one or more peaks covered by the third representative peak are continuous.

11. The method of claim 1, wherein a peak contour is an actual contour without approximation.

12. The method of claim 1, further comprising:
performing a first source mask optimization to the subset of critical patterns;
performing a first mask optimization verification to identify one or more feature limiters;
adjusting layout retarget rules based on the identified one or more feature limiters and generating a set of clips based on the adjusted layout retarget rules;
performing a second source mask optimization to the subset of critical patterns and the generated set of clips to obtain an optimized source;
performing a second mask optimization verification to the plurality of patterns with the optimized source according to the adjusted layout retarget rules;
determining whether one or more hot spots are identified in the design layout; and
in accordance with determining that no hot spot is identified, adopting the optimized source and the adjusted layout retarget rules for a full chip design.

13. (canceled)

14. The method of claim 1, wherein the subset of critical patterns are used in at least one selected from: optical proximity correction (OPC), defect inspection, defect prediction, or source mask optimization (SMO).

15. A non-transitory computer readable medium that stores a set of instructions that is executable by at least one processor of a system to cause the system to at least:
access diffraction order data based on a plurality of patterns of a design layout that represent features to be formed on at least a portion of a substrate, the diffraction order data including a plurality of peaks corresponding to the plurality of patterns;
identify a subset of representative peaks from the plurality of peaks according to one or more grouping criteria, the identification of the subset comprising identification of a first representative peak of the subset of representative peaks that covers another peak colinear with the first representative peak, wherein the first representative peak is a discrete peak having a frequency that is an integer multiple of frequency of another discrete peak; and
select a subset of critical patterns corresponding to the subset of representative peaks.

16. The medium of claim 15, wherein the diffraction order data represents a plurality of diffraction order maps.

17. The medium of claim 15, wherein the instructions are further configured to cause the system to:
extract peak centers and peak contours of the plurality of peaks; and
classify the plurality of peaks into discrete peaks and continuous peaks.

18. The medium of claim 15, wherein the instructions configured to cause the system to identify the subset of representative peaks are further configured to cause the system to identify a second representative peak of the subset of representative peaks that covers one or more other peaks with respective peak centers that are located within a predetermined distance from a peak center of the first representative peak, wherein the second representative peak is a discrete peak, and the one or more peaks covered by the second representative peak include a discrete peak or a continuous peak.

19. The medium of claim 15, wherein the instructions configured to cause the system to identify the subset of representative peaks are further configured to cause the system to identify a third representative peak of the subset of representative peaks that covers one or more other peaks with respective peak centers located within a peak contour of the third representative peak, wherein the third representative peak is a continuous peak and located in an unlimited direction, and the one or more peaks covered by the third representative peak are continuous.

20. The medium of claim 15, wherein the instructions are further configured to cause the system to:
perform a first source mask optimization to the subset of critical patterns;
perform a first mask optimization verification to identify one or more feature limiters;
adjust layout retarget rules based on the identified one or more feature limiters and generate a set of clips based on the adjusted layout retarget rules;
perform a second source mask optimization to the subset of critical patterns and the generated set of clips to obtain an optimized source;
perform a second mask optimization verification to the plurality of patterns with the optimized source according to the adjusted layout retarget rules;
determine whether one or more hot spots are identified in the design layout; and
in accordance with a determination that no hot spot is identified, adopt the optimized source and the adjusted layout retarget rules for a full chip design.

21. The medium of claim 15, wherein the instructions are further configured to cause the system to use the subset of critical patterns in at least one selected from: optical proximity correction, defect inspection, defect prediction, or source mask optimization.
